(19) United States
(12) Patent Application Publication
(10) Pub. No.: US 2010/0285241 A1
(43) Pub. Date: Nov. 11, 2010

(54) Laser deposition of nanocomposite films

(75) Inventor: Hee Kuwon Park, San Jose, CA (US)

Correspondence Address: RONALD V. DAVIDGE, 5103 Madison Lakes Circle, Davie, FL, 33328, US

(73) Assignee: ApplliFlex LLC

(21) Appl. No.: 11/975,867

(22) Filed: Oct. 22, 2007

(51) Int. Cl. C23C 16/48

(52) U.S. Cl. 427/596; 977/742

(57) ABSTRACT

A nanocomposite layer is deposited on a surface of a substrate by a process including: a) moving a laser bean along a target including a polymer and a plurality of nanoparticles, b) vaporizing a portion of the polymer into a gaseous form, and c) transferring the portion of the polymer in the gaseous form, and a portion of the nanoparticles from the target to the surface of the substrate. The target may be divided into a first section holding the nanoparticles and a second section including the polymer, or the target may include a mixture of the nanoparticles and the polymer.

### BACKGROUND OF THE INVENTION

1. Field of Invention

This invention relates to a process for manufacturing a nanocomposite film comprising nanoparticles in a polymer matrix and more particularly to the laser deposition of such a film on a substrate.

2. Summary of the Background Art

Organic light emitting devices (OLEDS) are being developed for a variety of display screen applications. In general an OLED is a multi-layered device having a light emitting layer in which a photon is generated whenever an electron and a hole combine. A significant problem with the OLED arises from the fact that the vast majority of the photons generated within the light emitting layer are not coupled or transmitted from the device, because the photons strike the surfaces of the light emitting layer at angles of incidence that are above the critical angles so that internal reflection occurs without transmission from the light emitting layer. There have been estimates that less than 20 percent of the photons generated within the light emitting layer leave the light emitting layer due to this problem.

The patent literature includes a number of descriptions of an OLED having a light modifying layer adjacent the light emitting layer with the light modifying layer having refractive properties allowing a greater percentage of light from the light emitting layer to be transmitted into the light modifying layer and with the light modifying layer additionally having refractive or reflective properties causing light received from the light emitting layer to be emitted from the light modifying layer at suitable angles for visibility of the image generated within the light emitting layer.

For example U.S. Pat. No. 7,012,363 describes an OLED device including a substrate and an active region positioned on the substrate, wherein the active region comprises an anode layer, a cathode layer, and a light emitting layer. The OLED device additionally includes a light modifying layer in the form of a polymeric layer disposed over the active region, under the active region, or both over and under the active region. The polymeric layer has micro-particles incorporated therein, which are effective to increase the outcoupling efficiency of the OLED, so that a higher percentage of the photons generated within the light emitting layer leave the device as visible light. In one embodiment, the OLED device comprises a composite barrier layer, with the microparticles being incorporated in a polymeric planarizing sublayer of the composite barrier layer. The composite barrier layer in this embodiment also protects the OLED from damage caused by environmental elements such as moisture and oxygen. The polymeric sublayer has microparticles incorporated therein to increase the outcoupling efficiency of the OLED. In a preferred embodiment the OLED is provided with a composite layer disposed over the active region and or on a surface of the substrate. In some embodiments the micro-particles are incorporated within a polymeric polarizing sub layer closest to the substrate. The microparticles are preferably composed of an inorganic material, such as a metal or metal oxide like titanium dioxide, or of a ceramic material having a relatively high index of refraction. Preferably the micro-particles have an index of refraction greater than about 1.7. In addition, the micro-particles are preferably substantially smaller than the largest dimension of any active region or pixel in the display comprising the OLED device. Furthermore, the micro-particles preferably have a size greater than the wavelength of light generated by the OLED.

U.S. Pat. No. 6,965,197 describes an enhanced light extraction OLED device including a transparent substrate, a light modifying layer in the form of a light scattering layer disposed over a surface of the transparent substrate, a transparent first electrode layer disposed over the light scattering layer, an organic electroluminescent element disposed over the transparent first electrode layer, and a transparent second electrode layer disposed over the organic electroluminescent element. The electroluminescent element includes one or more organic layers having at least one light emitting layer in which light is produced. The light scattering layer can consist of scattering centers embedded in a matrix, and can alternately or additionally include textures or microstructures on a surface of the layer. When scattering centers are embedded in the matrix, the optical index of the matrix needs to be comparable to, or larger than, that of the organic electroluminescent element, and preferably not smaller than 0.9 thereof, so that the light can enter the scattering layer efficiently. The matrix of the light scattering layer can be a polymer coated in a thin layer of film, a solution from a melt, or other suitable forms. It can also be a monomer and polymerized after being coated as a thin film by UV light, heat, or other suitable means. Common coating techniques, such as spin coating, blade coating, screen printing etc. can be appropriately selected. Alternately the scattering layer can be a separate element laminated on the surface of the top electrode layer, or to the substrate, depending on the desired location of the scattering layer in the OLED device structure. The index of the scattering centers needs to be significantly different than that of the matrix and preferably different by more than 5 percent from the index value of the light emitting layer. The scattering centers can include particles, with exemplary particle materials being TiO₂, Sb₂O₃, CaO, In₂O₃, or it can include voids or air bubbles. The size of the particles must be compatible to the wavelength of light to be scattered, with the size ranging from several tens of nanometers to several microns. The thickness of the scattering layer can range from less than one micron to several microns. The thickness and the loading of particles in the matrix needs to be optimized to achieve optimum light extraction from a particular OLED device.

U.S. Pat. No. 6,777,871 describes an OLED containing a first electrode, a second electrode, at least one organic light emitting layer, and a light modifying layer in the form of an output coupler which reduces a Fresnel loss. The index of refraction of the output coupler is matched to that of the adjacent layer of the device. The output coupler may be a dimpled transparent material or a composite layer containing light scattering particles to allow the reduction of critical angle loss. For example, in one embodiment, the light scattering layer or output coupler includes a thermoplastic, thermoset, or elastomeric material that is transparent and that can be molded into a desired structure. The material, which is, for example, a polymer or a glass material, is placed into a mold cavity having a corrugated or dimpled surface. The material is then solidified to form the shape transparent material having corrugated or dimpled first light emitting surface. The index of refraction of the material can be adjusted to match that of the surface of the electroluminescent device by mixing nanoparticles of high refractive index such as TiO₂ or ZnO particles into the thermoplastic, thermoset, or elastomeric materials before or after the material is placed into the mold. In this manner the refractive index of the resulting composite can be adjusted between the values of the pure polymer or glass material and the pure filler formed by the nanoparticles.

U.S. Pat. No. 7,046,439 describes an optical element with a specified range of surface roughness, containing a dispersion of minute particles having a particle size dimension less than 100 nanometers, and preferably less than 35 nanometers. When sized below 50 nanometers, these particles do not scatter light significantly and therefore do not affect the scattering characteristics of the optical element significantly. More preferably, particles have a particle size dimension of less than 15 nanometers, being sufficiently smaller than the wavelength of visible light so that they do not cause scattering of light and can therefore be used to change the index of refraction of materials without impacting their scattering, light transmission, and light reflection characteristics significantly. This size range additionally facilitates dispersion of the particles into the polymer matrix. Furthermore if the particles aggregate to form clusters of 2 or 3 particles that in turn act as one particle, the particle size dimensions of the aggregated particle is still too small to significantly effect the transmission properties of the optical element.

U.S. Pat. Appl. Pub. No. 2007/0042174 A1 describes a method of fabricating a nanocomposite material, with the method including generating nanoparticles in-situ with a polymer. The nanoparticles are characterized by a shorter dimension of not more than 50 nanometers and by elongated strands or dense packing.

U.S. Pat. No. 6,998,156 describes the transfer of solid target material onto a substrate, with material from the target being ablated as it is vaporized by irradiation with intense light of a resonant vibrational mode of the target material, and with the vaporized material then being deposited on a substrate in a solid form. The target material, which is, for example, a polymeric material, is vaporized with an infrared laser beam that resonantly excites the vibrational mode of the material, transferring the material to the substrate in a gaseous phase and depositing the vapor onto a substrate, for example without photochemical or other modifications of the target material. This process takes advantage of the molecular structure of the material and uses mode-specific heating to localize and control the deposited laser energy. The highly vibrationally excited material remains in its ground electronic state but has sufficient internal energy to overcome intermolecular binding energy of the material and be transported into the gas phase, usually without significant photochemical modification, including rupture of the bonds between repeating units of a polymeric material. The mode specific heating of the resonant excitation allows deposition of a wide variety of photochemically and thermally unstable or labile materials in thin film form. The non-electronic, resonant infrared laser deposition is characterized by the selection of a band in the infrared absorption spectrum of the coating material, particularly polymeric coating material. The operational region in the absorption spectrum corresponds to molecular vibrational states in the approximate region of 100-5000 cm⁻¹. particularly the infrared region of 1-15 microns, and especially 2-10 microns. Transfer of sufficient energy to a coating target material is made to cause desorption of the target material and deposition thereof from a vapor state onto a substrate without degradation. Only enough energy is transferred to the target material to keep the material in its ground electronic state and below an excited electronic excitated state.

As reported in Proc. Of SPIE Vol. 6459 64590X-1 to 64590X-6 by Michael R. Papantonakis et al., layers of functionalized nanoparticles have been fabricated using an infrared laser based deposition technique. A frozen suspension of nanoparticles were ablated with a laser tuned to a vibrational mode of the solvent resulting in the fabrication of the matrix and ejection of the nanoparticles. The solvent was pumped away and the nanoparticles were collected by a receiving substrate in a conformal process. Photoluminescence measurements of nanoparticles containing two common dyes showed no significant change to the emission properties of either dye, suggesting that no damage occurred during the laser ablation process. The process is generally applicable to particles of various size and shapes and chemistries provided that an appropriate solvent is chosen. In one example TiO₂ nanoparticles 50 to 100 nanometers in size were transferred to a silicon substrate.

What is needed is a process for forming a light modifying layer, such as a nanocomposite layer including nanoparticles in a polymeric matrix, on the surface of a substrate, without the presence of a solvent within the light modifying layer as it is being formed on the surface, so that the substrate will not be damaged by contact with the solvent. Such a process could be used to coat the layer on a substrate including elements sensitive to such damage.

### SUMMARY OF THE INVENTION

In accordance with one aspect of the invention, a process is provided for depositing a nanocomposite layer on a surface of a substrate. The process includes: a) moving a laser beam along a target including a polymer and a plurality of nanoparticles, b) vaporizing a portion of the polymer into a gaseous form, and c) transferring the portion of the polymer in the gaseous form, and a portion of the nanoparticles from the target to the surface of the substrate.

In one embodiment of the invention, the target includes a first target section holding the nanoparticles and a second target section, separate from the first target section, comprising the polymer. The laser beam may be an infrared laser beam having a frequency resonant with a vibrational mode of the polymer. Alternately, the laser beam may be resonant with a vibrational mode of a liquid in which the nanoparticles are suspended, or the laser beam may be resonant with vibration modes of both the polymer and the liquid.

In another embodiment of the invention, target comprises a mixture of the polymer and the nanoparticles. Again, the laser beam may be an infrared laser beam having a frequency resonant with a vibrational mode of the polymer. The mixture may also include a solvent dissolving the polymer but not the nanoparticles, with the mixture being frozen before the laser beam is moved along the surface of the substrate. The laser beam may be resonant with a vibrational mode of the solvent or with both a vibration mode of the polymer and a vibrational mode of the solvent.

The nanoparticles may include metal or metal oxide particles having diameters less than 1 micrometer. The substrate may include a light emitting layer, with the nanocomposite layer modifying directions of light generated within the light emitting layer. Alternately, the substrate may include a photovoltaic cell, with the nanocomposite layer being both transparent and electrically conductive. Alternately, the substrate may include a medical device, such as an implant, with the polymer composing a material that is gradually eroded by contact with a body fluid, and with the nanoparticles composing a medicine having a therapeutic effect.

### BRIEF DESCRIPTION OF THE INVENTION

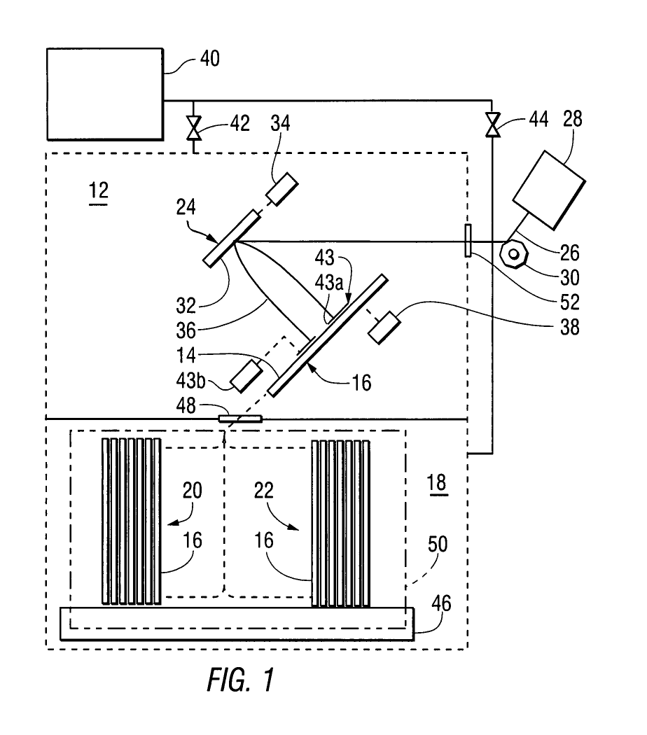

FIG. 1 is a schematic view of apparatus for carrying out the process of the invention;

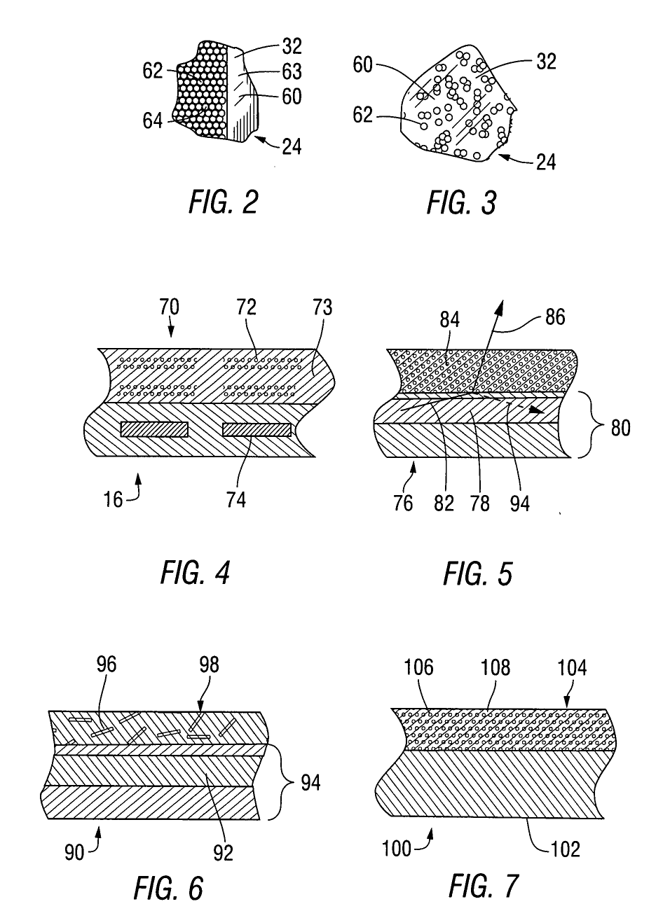

FIG. 2 is a fragmentary plan view of a lower surface of a target within the apparatus of FIG. 1;

FIG. 3 is a fragmentary plan view of an alternative lower surface of a target within the apparatus of FIG. 1;

FIG. 4 is a fragmentary cross-sectional view of a substrate having a nanocomposite layer applied within the apparatus of FIG. 1;

FIG. 5 is a fragmentary cross sectional view of a display screen having a nanocomposite layer applied within the apparatus of FIG. 1;

FIG. 6 is a fragmentary cross sectional view of a solar cell having a nanocomposite layer applied within the apparatus of FIG. 1; and

FIG. 7 is a fragmentary cross sectional view of a medical implant having a nanocomposite layer applied within the apparatus of FIG. 1;

### DETAILED DESCRIPTION OF THE INVENTION

FIG. 1 is a schematic view of apparatus 10 for carrying out the process of the invention. The apparatus 10 preferably includes a process chamber 12, in which a nanocomposite film is formed on an upper surface 14 of a substrate 16, and a supply chamber 18, holding a first plurality 20 of substrates 16 that have not yet been processed and a second plurality 22 of substrates 16 that have already been processed. The process chamber 12 includes a target 24 from which material is ablated using a beam 26 from a laser 28. Preferably, the laser beam 26 is moved along the surface of the target 24 by means of a beam rastering device such as a spinning multifaceted mirror or a scanning mirror 30 to form a raster pattern. Preferably, the target 24 is moved in both directions perpendicular to its lower surface 32 by means of a target mechanical drive 34. Movement of the target 24 and the laser beam 26 may be used to present new material within the target 24 to the ablation process. In addition such movement of the target 24 and the laser beam 26 may be used to present different types of material on the lower surface 32 of the target 24 to the ablation process.

During the ablation process, material from the lower surface 32 of the target 24 forms an ablation plume 36 in which material is transferred to the upper surface 14 of the substrate 16 to form a nanocomposite film thereon. The substrate 16 within the upper chamber 12 is moved in both directions perpendicular to its upper surface 14 by a substrate mechanical drive 38 to obtain uniform coverage of the upper surface 14 of the substrate 16 with material deposited by the plume 36, or, if desired, to obtain non-uniform coverage according to a predetermined pattern for such coverage. The ablation process occurs in a moderate vacuum maintained within the process chamber 12 by a vacuum pump 40 connected to the process chamber 12 through a valve 42.

Optionally, a shadow mask 43, having an aperture 43a may be held adjacent the upper surface 14 of the substrate 16 to limit the portion of this substrate 16 acted upon by the ablation process. To achieve various patterns in the material being deposited, the shadow mask 43 may be held stationary, stepped along the surface 14, or moved with the surface 14. Optionally, a mask drive 43b is used to move the shadow mask 43.

In the example of a FIG. 1, the vacuum pump 40 is additionally connected to the supply chamber 18 through a valve 44. The supply chamber 18 includes a substrate supply drive 46 which selects individual substrate 16 from the first plurality 20 of substrates 16 to be moved into the process chamber 12 through a door 48. When the process of forming a nanocomposite film has been completed on a substrate 16 within the process chamber 12, that substrate 16 is returned downward through the door 48 into the supply chamber 18 to be moved by the substrate supply drive 46 into the second plurality 22 of substrates 16. Preferably the supply chamber 18 additionally includes an external door 50 that is used to load substrates 16 into the first plurality thereof 20 and to remove substrates 16 from the second plurality thereof 22. Various devices may be placed outside the chambers 12, 18 of the apparatus 10. For example the laser 28 drives the ablation process with the beam 26 directed through a window 52 into the process chamber 12.

While a single vacuum pump 40 is shown in the example of FIG. 1, separate vacuum pumps may be applied to the process chamber 12 and the storage chamber 18 to better meet the requirements for both of these chambers. In any case the vacuum applied to the process chamber 12 must be sufficient to remove vapors released by the ablation process from this chamber 12 so that a suitable vacuum can be maintained, and the vacuum applied to the storage chamber 18 must be sufficient to pump down this chamber after it has been opened to add and remove substrates 16.

While FIG. 1 shows the apparatus 10 configured for downward deposition of material to a substrate 16 disposed below the target 24, it is understood that such apparatus could alternatively be configured for upward deposition to a substrate disposed above a target.

FIGS. 2 and 3 are each fragmentary plan views of the lower surface 32 of target 24 showing alternative configurations for the material within the target 24. In either case the material in the target 24 includes a polymer 60 and a number of nanoparticles 62.

As shown in FIG. 2, the nanoparticles 62 may be placed in a cavity 64 separate from the polymer 60, so that the nanoparticles 62 and the polymer 60 form discrete target sections 63, 64, separate from one another. Preferably, the nanoparticles 62 are suspended in a liquid to facilitate handling, while the polymer 60 is provided as a target in a solid state, without a solvent.

In accordance with one embodiment of the invention, the discrete target sections 63, and 64 of FIG. 2 are irradiated with the laser beam 26 at an infrared frequency that resonantly excites the vibrational mode of the material composing the polymer 60, transferring the polymer material to the substrate in a gaseous phase and depositing the vapor onto the substrate 16, preferably without photochemical or other modifications of the target material. This process takes advantage of the molecular structure of the material and uses mode-specific heating to localize and control the deposited laser energy. The highly vibrationally excited material from the polymer 60 remains in its ground electronic state but has sufficient internal energy to overcome intermolecular binding energy of the material and to be transported into the gas phase, usually without significant photochemical modification, including rupture of the bonds between repeating units of a polymeric material. The mode specific heating of the resonant excitation allows deposition of a wide variety of photochemically and thermally unstable or labile materials in thin film form. The non-electronic, resonant infrared laser deposition is characterized by the selection of a band in the infrared absorption spectrum of the coating material, particularly polymeric coating material. The operational region in the absorption spectrum corresponds to molecular vibrational states in the approximate region of 100-5000 cm⁻¹, particularly the infrared region of 1-15 microns, and especially 2-10 microns. Transfer of sufficient energy to a coating target material is made to cause desorption of the target material and deposition thereof from a vapor state onto a substrate without degradation. Only enough energy is transferred to the target material from the polymer 60 to keep the material in its ground electronic state and below an excited electronic excited state. This aspect of the process for transferring a polymer from the target to a substrate is further described in U.S. Pat. No. 6,998,156 to Bubb et al, which is incorporated herein by reference.

For example, the appropriate wavelength of light, corresponding to resonant vibrational excitation, is determined by examining the infrared absorption spectrum of the target material that is to be transferred onto a substrate in solid form via laser evaporation. The infrared spectrum has characteristic absorption bands that are used to identify the chemical structure of the material. The resonant excitation wavelength can be determined by identifying the wavelength associated with one of the absorption bands, and then using a light source, such as a tunable laser in the infrared region or a fixed frequency laser that is resonant with the vibrational absorption band, to deliver the resonant energy to the target material, as by shining the light onto the material. Light of more than one resonant wavelength can be used. Deposition rates of a material vary depending on what resonant wavelength is used and the desired deposition rate can be measured and selected experimentally.

In accordance with another embodiment of the invention, the discrete targets 63, 64 of FIG. 2 are irradiated with the laser beam 26 at an infrared frequency that resonantly excites the vibrational mode of the liquid in which the nanoparticles 64 are suspended, facilitating the transfer of these nanoparticles 64 while the liquid is evaporated. Preferably, the liquid in which the nanoparticles 64 are suspended is chosen to have a vibrational mode frequency that is similar to a vibrational mode frequency of the polymer 60, with the targets 63, 64 being irradiated at an infrared frequency that excites the vibrational mode of both the liquid suspending the nanoparticles 64 and the polymer 60.

Alternately, as shown in FIG. 3, the nanoparticles 62 may be mixed with the polymer 60 in premixed material for the target 24. Preferably, the nanoparticles 62 and the polymer 60 are mixed with a solvent dissolving the polymer 60 but not dissolving the nanoparticles 62. The resulting mixture may then be frozen by being brought to a temperature lower than the freezing point of the solvent. For example, such freezing can be accomplished using liquid nitrogen. In the ablation process of the invention, the solvent is evaporated whether or not it has been frozen. As described above in reference to FIG. 2, material within the mixed target of FIG. 3 may be irradiated with the laser beam 26 at an infrared frequency that resonantly excites the vibrational mode of the material composing the polymer 60, achieving the advantages further described above. In another embodiment, material within the mixed target of FIG. 3 is irradiated with the laser beam 26 at an infrared frequency that resonantly excites the vibrational mode of the solvent within the material. The solvent within the material may be chosen to have a vibrational mode frequency that is similar to a vibrational mode frequency of the polymer 60, with the mixed material within the target being irradiated at an infrared frequency that excites the vibrational mode of both the solvent and the polymer 60.

FIG. 4 is a fragmentary cross sectional view of the substrate 16 following the application of the ablation process within the apparatus 10 showing that a nanocomposite layer 70 has been added to the substrate.

The polymer is for example a polymethyl methacrylate material (PMMA), a polytetrafluoroethylene material, a polyalphamethyl styrene material, or an electrically conductive polymer, such as PEDOT:PSS material. As described above, the polymer within the target 24 may be a solid form or a form that is at least softened by the addition of a solvent in accordance with a preferred method of the invention. During the ablation process, the solvent, if it is present within the polymer material of the target 24, is evaporated and the polymer itself is transferred to be built up within the nanocomposite layer 70. The vapor from the solvent or any other volatile material, such as the liquid in which the nanoparticles 62 of FIG. 2 are suspended, undergoing the ablation process is removed from the process chamber 12 by the vacuum pump 40. Also, during the ablation process the nanoparticles 62 are transferred from the target 24 to the nanocomposite film layer 70 being built up on the substrate. The process of transferring the nanoparticles 62 occurs without substantial change to the shape, physical properties, or chemical properties of the nanoparticles 62.

A significant advantage of the present invention over prior art methods for forming films on substrates arises from the fact that the process of building the nanocomposite film 70 on the substrate 16 is a dry process with dry material being added to the substrate. If a solvent for the polymer 60 is used in the process it is completely evaporated during ablation so that it is not transferred to the substrate 16 within the ablation plume 36. On the other hand, prior art methods for forming nanocomposite films require the presence of a solvent in the polymer as it is applied to the substrate and as nanoparticles are mixed with the polymer on the substrate. Such a use of a solvent severely limits the prior art processes for forming nanocomposite films, because the solvent present within the film being formed actually on the substrate can severely damage or destroy various layers or elements present within the substrate prior to the process of forming a nanocomposite film. (In this regard it is noted that the substrate as shown in FIG. 4 is defined as that combination of layers of material that are present going into the ablation process. In other words, this substrate may include many layers with elements producing light, conducting electricity, and so on that have previously been coated on another substrate which is part of the substrate of FIG. 4.)

In accordance with one embodiment of the invention the target 24 is configured as shown in FIG. 2, with the laser beam 26 being moved between the target sections 63, 64 to form regions of the nanocomposite layer 74 having different densities of the nanoparticles as the substrate 16 being coated is moved relative to the laser plume 36. For example, the movements of the laser beam 26 using the spinning or scanning mirror 30 and of the target 24 using the target drive mechanism 34 are coordinated with the movements of the substrate 16 under control of the substrate drive mechanism 38 so that the deposition of nanoparticles 62 within the nanocomposite film 70 is controlled to provide differing densities of particle deposition at differing areas within the nanocomposite layer 70. This technique can be used to cause such variations in density to occur both along the surface 14 of the substrate 16, in any direction along this surface 14, and within the nanocomposite layer 70 in a direction perpendicular to this surface 14. The optional shadow mask 43 may be used to to achiever sharper definition of the edges of regions of varying nanoparticle density.

As shown in the example of FIG. 4, nanoparticles 62 are concentrated in discrete layers 72 with surrounding layers 73 being formed entirely or almost entirely from the polymer material. These discrete layers may provide specific properties associated with multiple discreet layers of nanoparticles 62 and may additionally be positioned in relation to discrete components 74, such as light producing components, at specific locations within the substrate 16 on which the nanocomposite layer 70 is deposited.

For example the nanoparticles 62 may comprise spheres having diameters less than 1 micrometer, composed of a metal oxide, such as titanium dioxide, zinc oxide, or an oxide of zirconium.

FIG. 5 is a fragmentary cross sectional view of a display screen 76 built in accordance with the invention by the ablation process described above in reference to FIG. 1. The display screen 76 includes an OLED layer 78 within the substrate 80, which may also include other layers, such as layers required for electrical conductivity and mechanical support. Within the OLED layer 78, a number of photons travel in paths 82 that would result in total reflectance of the photons as indicated by arrow 84 within the substrate 80 in the absence of the nanocomposite layer 84. However, with the nanocomposite layer 84 formed on the substrate 80 in accordance with the present invention, the photon traveling along path 82 is refracted and/or reflected within the nanocomposite layer 84 to exit along a path 86 providing visibility outside of the display screen 76. In this way the brightness of the display from the display screen 76 is greatly enhanced. For example, the display screen 76 may be configured as described in U.S. Pat. No. 6,777,871 Duggal et al., or U.S. Pat. No. 6,965,197 to Tyan et al., or U.S. Pat. No. 7,012,363 to Weaver et al., each of which is incorporated herein by reference furthermore the nanocomposite layer 84 may be configured as described in U.S. Pat. No. 7,046,439 to Kaminsky et al. which is also incorporated herein by reference. Since the nanocomposite layer 84 is formed without depositing solvents on the surface of the substrate 80, elements within the OLED layer 78 and other layers of the substrate 80 are not damaged by exposure to a solvent during the formation of the nanocomposite layer 84. The nanocomposite layer 84 may also perform an encapsulation function, preventing the diffusion of atmospheric gases and moisture into the OLED layer 76.

FIG. 6 is a fragmentary cross-sectional view of a solar cell 90 built in accordance with the invention to include a photovoltaic element 92 within the substrate 94. Carbon nanotubes 96 comprise the nanoparticles within a nanocomposite layer 98, which may be additionally composed of an electrically conductive polymer, such as PEDOT:PSS (Poly(3,4-ethylenedioxythiophene) poly(styrenesulfonate)). The nanocomposite layer 98 is both transparent and electrically conductive, allowing electrical connections to be made to the photovoltaic element 92 through the layer 98 and additionally allowing light to pass through the layer 98 to the photovoltaic element 92. Alternately, metal nanoparticles, such as gold nanoparticles, may be used in place of the carbon nanotubes 96.

While FIG. 6 shows the application of a conductive and transparent nanocomposite layer to a photovoltaic element 92 within a solar cell 90, it is understood that a conductive and transparent nanocomposite layer may also be applied to a sublayer containing another type of optoelectronic element, as in, for example, a display device.

FIG. 7 is a fragmentary cross sectional elevation of a medical device 100 built in accordance with a third embodiment of the invention. A device structure 102 forms the substrate while the nanocomposite layer 104 includes a number of nanoparticles 106 composed of a medicine having a desired therapeutic effect and a polymer 108 that is gradually eroded by exposure to body fluids. For example the implant structure 102 may be formed as a stent with the nanoparticles 106 being formed to include a medicine reducing the likelihood of blood clotting following the insertion of the stent and with such a medicine being gradually provided within the blood stream as the polymer 108 is eroded by contact with blood.

While the invention has been described and shown in terms of its preferred embodiment it is understood that this description has only been given by way of example and that various changes can be made without departing from the spirit and scope of the invention as defined in the appended claims.

### EXAMPLES

The following examples of the process of the invention were performed in a deposition chamber configured for upward deposition, with the target located at the bottom, with the laser beam irradiating at 45 degree angle while scanning the surface of the target. The substrate holder could accommodate up to 101.6 mm wafers. The laser light source was the Vanderbilt University, Nashville, Tenn., free electron laser (FEL). The Vanderbilt FEL was continuously tunable from 2-10 μm. The laser pulse structure consists of a 30 Hz, 5 μs long macropulse which envelops some 10⁴ one picosecond pulses, each spaced by approximately 350 picoseconds. The laser beam is focused onto the target by a BaF₂ lens with the focal length of 500 mm. The single-macropulse energy as measured by a pyroelectric joulemeter was approximately 10 mJ, yielding a fluence of 1-2 J/cm² at the target surface and an average power on the order of 300 mW.

### Example 1

### Deposition of TiO₂ Nanoparticles and Polystyrene from a Premixed Target

TiO₂ nanoparticles were purchased from Sigma-Aldrich (part number 634662), where the particle size is less than 100 nm. Polystyrene polymer was purchased from Sigma-Aldrich (part number 182435).

Polystyrene was dissolved into 1,2 dichlorobenzene (DCB). TiO₂ nanoparticles were added to the solution (5% by weight). In order to aid the dispersion of TiO₂ nanoparticles, a small volume (approximately two drops per 100 ml) of surfactant (Liquinox) was added to the solution and the mixture was put into an ultrasonic bath for 5 minutes. The mixture was then pipetted into a target well (approximately 25 mm in diameter and 6 mm deep), composed of stainless steel, and flash frozen by dipping the target well into the bath of liquid nitrogen. Once frozen, the target was introduced into the chamber. A thermal insulation block made of Teflon® was inserted between the target and the target holder, keeping the target frozen during the deposition run. A 25.4 mm glass plate was used as a substrate, located approximately 37 mm away from the target. The laser wavelength was tuned to the resonant vibrational mode of DCB at 3.3 μm (C-H stretch mode). The vacuum chamber was evacuated to the vacuum pressure level at 1×10⁻⁴ torr and maintained during the deposition run, although the vacuum pressure increased slightly (to about 2˜5×10⁻⁴ torr, depending on the laser power) when the laser was turned on. The laser power was fixed at 10 mJ during the deposition run for 5 minutes. The laser beam was rasterized over the target surface to uniformly cover the target surface. During the deposition, volatile organic solvents were pumped away. After the deposition run, the laser shutter was closed and the vacuum chamber was vented out to ambient air.

The deposited film on a glass substrate was inspected under an optical microscope. The film exhibited a uniform mixture of TiO₂ nanoparticles inside polystyrene film, although the film morphology was, in general, quite rough.

### Example 2

### Deposition of TiO₂ Nanoparticles and Polystyrene from Discrete Targets

TiO₂ nanoparticles were purchased from Sigma-Aldrich (part number 634662), where the particle size is less than 100 nm. Polystyrene polymer was purchased from Sigma-Aldrich (part number 182435).

Polystyrene pellets were heated over the glass transition temperature (approximately 95° C.) inside a target well and subsequently cooled town to form a clear, solid target of polystyrene. TiO₂ nanoparticles were suspended in an isopropyl alcohol (IPA) (5% by weight) and stirred vigorously. A TiO₂ nanoparticle suspension in IPA is very stable without a surfactant, making it an ideal candidate for the deposition. The TiO₂-IPA mixture was then pipetted into a target well (approximately 25 mm in diameter and 6 mm deep), composed of stainless steel, and flash frozen by dipping the target well into the bath of liquid nitrogen Once frozen, the target was introduced into the chamber. A thermal insulation block made of Teflon® was inserted between the target and the target holder, keeping the target frozen during the deposition run. A polystyrene target was also introduced into the chamber. The two targets were introduced sequentially to encapsulate the TiO₂ nanoparticles with polystyrene, with the TiO₂ target being introduced before the polystyrene target. A 25 mm glass plate was used as a substrate, located approximately 37 mm away from the target. The laser wavelength was tuned to the resonant vibrational mode of polystyrene and IPA at 3.3 μm (C-H stretch mode for both). The vacuum chamber was evacuated to the vacuum pressure level at 1×10⁻⁴ torr and generally maintained during the deposition run, although the vacuum pressure increased slightly (to about 2˜5×10⁻⁴ torr, depending on the laser power), when the laser was turned on. The laser power was fixed at 10 mJ during the deposition run for 5 minutes for the TiO₂/IPA target followed by another 5 minutes for the bulk polystyrene target. The laser beam was rasterized over each target surface to uniformly cover the target surface. During the deposition, volatile organic solvents are pumped away. After the deposition run, the laser shutter was closed and the vacuum chamber was vented to ambient air.

The deposited film on a glass substrate was inspected under an optical microscope. The film exhibited a uniform mixture of TiO₂ nanoparticles and polystyrene. The film morphology was good,

To demonstrate the increased light extraction effect of TiO₂ nanoparticles on an OLED (Organic Light Emitting Device), the TiO₂/polystyrene nanocomposite films was deposited on top of Alq³ (Tris-(8-hydroxyquinoline)aluminum) layer through a shadow mask. The resulting film was illuminated under an ultraviolet (UV) lamp, inducing the photoluminescence of Alq3 molecules. On the area where the TiO₂/polystyrene nanocomposite film was deposited, an increase of brightness was observed, demonstrating the brightness enhancement effect.

### Example 3

### Deposition of TiO₂ Nanoparticles and Polymethyl Methacrylate (PMMA) from Discrete Targets

TiO₂ nanoparticles were purchased from Sigma-Aldrich (part number 634662), where the particle size is less than 100 nm. PMMA polymer was purchased from Sigma-Aldrich (part number 370037).

PMMA powders were heated over the glass transition temperature (˜105° C.) inside a target well and subsequently cooled town, forming a clear, solid target of PMMA. TiO₂ nanoparticles were suspended in an isopropyl alcohol (IPA) (5% by weight) and stirred vigorously. TiO₂ nanoparticles suspension in IPA is very stable without any surfactant, making it an ideal candidate for the deposition. The TiO₂/IPA mixture was then pipetted into a target well (approximately 25 mm in diameter and 6 mm deep), composed of stainless steel, and flash frozen by dipping the target well into the bath of liquid nitrogen. All other experiment conditions were the same as those of EXAMPLE 2, except for the laser wavelength and power. The laser wavelength was tuned to the resonant vibrational mode of PMMA and IPA at 3.38 μm (C-H stretch mode for both). The laser power was fixed at 10 mJ during the first deposition run for 5 minutes for the TiO₂/IPA target followed by another 5 minutes at 5 mJ laser power for the bulk PMMA target. After the deposition run, the laser shutter was closed and the vacuum chamber was vented to ambient air.

The deposited film on a glass substrate was inspected under an optical microscope. The film exhibited a uniform mixture of TiO₂ nanoparticles and PMMA. The film morphology was quite similar to the film obtained at EXAMPLE 2.

### Example 4

### Deposition of Gold Nanoparticles and PEDOT:PSS from a Premixed Target

Gold nanoparticles were purchased from Sigma-Aldrich (part number 636347), where the particle size is less than 100 nm. PEDOT:PSS (Poly(3,4-ethylenedioxythiophene) poly(styrenesulfonate)) conducting polymer was purchased from H. C. Starck (part number Baytron®-P), which is an aqueous dispersion of the intrinsically conductive polymer PEDOT:PSS (1.2˜1.4% in water).

First, PEDOT:PSS aqueous solution was mixed with N-Methylpyrrolidone (NMP). NMP is a conductivity enhancer for PEDOT:PSS and helps to obtain a smoother film. Then gold nanoparticles were added to the PEDOT:PSS/NMP mixture (4% by weight). The mixture was put into an ultrasonic bath for 5 minutes for a better dispersion. The mixture was then pipetted into a target well (approximately 25 mm in diameter and 6 mm deep), composed of stainless steel, and flash frozen by dipping the target well into a bath of liquid nitrogen. Once frozen, the target was introduced into the chamber. A thermal insulation block made of Teflon® was inserted between the target and the target holder, keeping the target frozen during the deposition run. A 25.4 mm glass plate was used as a substrate, located approximately 37 mm away from the target. The target-to-substrate distance is variable in this setup. The laser wavelength was tuned to the resonant vibrational mode of water at 3.0 μm (O-H stretch mode of water molecule). The vacuum chamber was evacuated to the vacuum pressure level at 1×10⁻⁴ torr and generally maintained during the deposition run, although the vacuum pressure increased slightly (to about 2˜5×10⁻⁴ torr, depending on the laser power) when the laser was turned on. During the deposition, volatile organic solvents are pumped away. The laser power was fixed at 25 mJ during the deposition run for 10 minutes. The laser beam was rastered over the target surface to uniformly cover the target surface. After the deposition run, the laser shutter was closed and the vacuum chamber was vented out to ambient air.

The deposited film on a glass substrate was inspected under an optical microscope. The film exhibited gold nanoparticles uniformly embedded in a PEDOT:PSS film, enhancing the conductivity of PEDOT:PSS film as a transparent conductive film.

What is claimed is:

1. A process for depositing a nanocomposite layer on a surface of a substrate, comprising:
moving a laser beam along a target including a polymer and a plurality of nanoparticles;
vaporizing a portion of the polymer into a gaseous form; and
transferring the portion of the polymer in a gaseous form and a portion of the nanoparticles from the target to the surface of the substrate within an ablation plume extending from the target to the surface of the substrate.

2. The process of claim 1, wherein the target includes a first target section holding the nanoparticles and a second target section, separate from the first target system, comprising the polymer.

3. The process of claim 2, wherein the laser beam is an infrared laser beam having a frequency resonant with a vibrational mode of the polymer.

4. The process of claim 2, wherein the nanoparticles are suspended in a liquid within the first target section.

5. The process of claim 4, wherein the laser beam is an infrared laser beam having a frequency resonant with a vibrational mode of the liquid within the first target section.

6. The process of claim 5, wherein the laser beam frequency is additionally resonant with a vibrational mode of the polymer.

7. The process of claim 2, wherein the laser beam is moved between the first target section and the second target section as the substrate is moved relative to the ablation plume to produce regions having varying densities of nanoparticles within the nanocomposite layer.

8. The process of claim 1, wherein the target comprises a mixture of the polymer and the nanoparticles.

9. The process of claim 8, wherein the laser beam is an infrared laser beam having a frequency resonant with a vibrational mode of the polymer.

10. The process of claim 8, wherein the target additionally comprises a solvent dissolving the polymer and suspending the nanoparticles.

11. The process of claim 8, additionally comprising freezing the mixture before moving the laser beam along the target.

12. The process of claim 11, wherein the laser beam is an infrared laser beam having a frequency resonant with a vibrational mode of the solvent dissolving the polymer and suspending nanoparticles.

13. The process of claim 1, wherein the laser beam frequency is additionally resonant with a vibrational mode of the polymer.

14. The process of claim 1, wherein the nanoparticles comprise metal oxides having diameters in the range from 1 nanometer to 100 micrometers.

15. The process of claim 1, wherein the nanoparticles comprise metals or carbon nanotubes, having diameters in the range from 1 nanometer to 100 micrometers.

16. The process of claim 1, wherein the substrate comprises an OLED layer, and wherein the nanocomposite layer modifies directions of light generated within the OLED layer.

17. The process of claim 16, wherein the nanocomposite layer additionally encapsulates portions of the substrate, preventing diffusion of atmospheric gases and moisture into the substrate.

18. The process of claim 1, wherein the substrate comprises an optoelectonic device, and wherein the nanocomposite layer is electrically conductive and transparent.

19. The process of claim 1, wherein the substrate comprises a medical device, wherein the polymer is eroded by contact with a body fluid, and wherein the nanoparticles include a medicine having a therapeutic effect.

20. The process of claim 1, wherein the portion of the polymer and the portion of the nanoparticles are transferred to the surface of the substrate through an aperture within a shadow mask disposed adjacent the surface of the substrate.
